(19) United States
(12) Patent Application Publication
(10) Pub. No.: US 2025/0174471 A1
(43) Pub. Date: May 29, 2025

(54) SUBSTRATE PROCESSING APPARATUS AND SUBSTRATE PROCESSING METHOD

(71) Applicant: SEMES CO., LTD., Cheonan-si (KR)

(72) Inventors: Jung Eun PARK, Seongnam-si (KR); Seong Soo LEE, Suwon-si (KR)

(73) Assignee: SEMES CO., LTD., Cheonan-si (KR)

(21) Appl. No.: 18/939,812

(22) Filed: Nov. 7, 2024

(30) Foreign Application Priority Data
Nov. 24, 2023 (KR) 10-2023-0165716

(51) Int. Cl. H01L 21/67; B08B 3/02

(52) U.S. Cl. CPC H01L 21/67023; B08B 3/02

(57) ABSTRACT

Disclosed is an apparatus for processing a substrate, the apparatus including: a chamber having a processing space for processing a substrate; a support unit disposed in the processing space and for supporting the substrate; a nozzle for discharging a treatment solution onto the substrate when processing the substrate; and a liquid supply unit for supplying the nozzle with the treatment solution, in which the liquid supply unit includes: a liquid supply source for supplying the treatment solution; a supply line connected between the liquid supply source and the nozzle; a supply valve installed on the supply line and opening and closing a passage of the supply line; a discharge line connected to the supply line downstream of the supply valve and discharging the treatment solution from the supply line; and a drain valve installed on the discharge line and opening and closing a passage of the discharge line.

### CROSS-REFERENCE TO RELATED APPLICATIONS

This application claims priority to and the benefit of Korean Patent Application No. 10-2023-0165716 filed in the Korean Intellectual Property Office on Nov. 24, 2023, the entire contents of which are incorporated herein by reference.

### TECHNICAL FIELD

The present invention relates to a substrate processing apparatus and a substrate processing method for processing a substrate.

### BACKGROUND ART

To manufacture semiconductor devices, various processes, such as photography, deposition, ashing, etching, and ion implantation, are performed. In addition, before and after these processes are performed, a cleaning process of cleaning particles remaining on the substrate is performed.

Among the processes described above, there is a wet etching process, which processes a substrate by discharging a treatment solution onto the substrate.

In the wet etching process, the valve is set to an open state when the treatment solution is supplied to the substrate, and the valve is set to a closed state when the supply of the treatment solution is stopped.

In this case, when the valve is switched from the open state to the closed state, a strong bubble is generated around a disk of the valve due to the pressure difference between an input end and an output end of the valve, and the disk is microscopically abraded along with the bubble, causing particles.

As a result, the bubbles and particles are discharged to the substrate along with the treatment solution through the nozzle, causing process failure.

### SUMMARY OF THE INVENTION

The present invention has been made in an effort to provide a substrate processing apparatus and a substrate processing method, which prevent process failure from occurring by preventing bubbles generated by a valve from being discharged through a nozzle when discharging a treatment solution through the nozzle.

The problem to be solved by the present invention is not limited to the above-mentioned problems, and the problems not mentioned will be clearly understood by those skilled in the art from the descriptions below.

An exemplary embodiment of the present invention provides an apparatus for processing a substrate, the apparatus including: a chamber having a processing space for processing a substrate; a support unit disposed in the processing space and for supporting the substrate; a nozzle for discharging a treatment solution onto the substrate when processing the substrate; and a liquid supply unit for supplying the nozzle with the treatment solution, in which the liquid supply unit includes: a liquid supply source for supplying the treatment solution; a supply line connected between the liquid supply source and the nozzle; a supply valve installed on the supply line and opening and closing a passage of the supply line; a discharge line connected to the supply line downstream of the supply valve and discharging the treatment solution from the supply line; and a drain valve installed on the discharge line and opening and closing a passage of the discharge line.

According to the exemplary embodiment, the discharge line may be connected to the supply line so as to extend downwardly from the supply line.

According to the exemplary embodiment, the drain valve may be disposed at a lower position than the supply valve.

According to the exemplary embodiment, the liquid supply unit may further include an intermediate valve that is installed in the supply line, but is installed downstream of the supply valve.

According to the exemplary embodiment, the apparatus may further include a controller for controlling the supply valve, the drain valve, and the intermediate valve, in which the controller may control the intermediate valve and the supply valve such that the intermediate valve is set to a closed state before the supply valve before the supply valve is set from an open state to a closed state.

According to the exemplary embodiment, the intermediate valve may be disposed at a lower position than the supply valve.

According to the exemplary embodiment, the intermediate valve may be a diaphragm valve of which opening and closing of a disk is controlled by a solenoid.

According to the exemplary embodiment, the supply line may include: a first line in which the supply valve is installed; and a second line extending from the first line and positioned lower than the first line, and the discharge line may be connected to the second line.

According to the exemplary embodiment, the supply line may further include a third line connected upwardly from the second line and connected with the nozzle, and a top end of the third line may be higher than a top end of the first line and a top end of the second line.

According to the exemplary embodiment, the apparatus may further include a controller for controlling the supply valve and the drain valve, in which when, in the supply line, the supply line is in a closed state and the drain valve is in an open state by the controller, an upstream side of the supply valve may be sealed and a downstream side of the supply valve may be exposed to atmospheric pressure to cause the treatment solution to be drained by free fall.

According to the exemplary embodiment, the supply valve and the drain valve may be diaphragm valves of which opening and closing of a disk is controlled by a solenoid.

Another exemplary embodiment of the present invention provides a method of processing a substrate by a substrate processing apparatus that includes a nozzle for discharging a treatment solution to a substrate, a liquid supply source for supplying the treatment solution, a supply line connected between the liquid supply source and the nozzle, a supply valve installed on the supply line and opening and closing a passage of the supply line, an intermediate valve installed in the supply line, but installed downstream of the supply valve, a discharge line connected to the supply line downstream of the supply valve and discharging the treatment solution from the supply line, and a drain valve installed on the discharge line and opening and closing a passage of the discharge line, the method including: a liquid discharge operation in which the supply valve is set to an open state to allow the treatment solution to be supplied from the supply line to the nozzle; and a treatment solution discharge operation in which the intermediate valve is set to a closed state to cause a bubble to form, and the drain valve is set to an open state to discharge the bubble and the treatment solution around the bubble through the discharge line.

According to the exemplary embodiment, the treatment solution discharge operation may include a discharge stop operation in which the intermediate valve installed in the supply line is set from an open state to a closed state to generate a bubble around the intermediate valve, and the supply valve installed upstream of the intermediate valve is set to an open state.

According to the exemplary embodiment, the treatment solution discharge operation may further include a drain ready operation of setting the supply valve to a closed state.

According to the exemplary embodiment, the treatment solution discharge operation may further include a drain operation of setting the intermediate valve to an open state and setting the drain valve to an open state to discharge the bubble and the treatment solution around the bubble through the discharge line.

According to the exemplary embodiment, the treatment solution discharge operation may further include a waiting operation of setting the drain value in a close state after the bubble and the treatment solution around the bubble are discharged through the discharge line.

According to the exemplary embodiment, when the supply valve is in the closed state and the drain valve is in the open state, an upstream side of the supply valve may be formed in a sealed state and a downstream side of the supply valve may be formed in a state exposed to atmospheric pressure so that the treatment solution is drained by free fall.

According to the exemplary embodiment, in the treatment solution discharge operation, the discharge line may be connected downwardly from the supply line to cause the bubble to free fall into the discharge line.

According to the exemplary embodiment, the intermediate valve may be provided by a diaphragm valve of which opening and closing of a disk is controlled by a solenoid.

Still another exemplary embodiment of the present invention provides an apparatus for processing a substrate, the apparatus including: a chamber having a processing space for processing a substrate; a support unit disposed in the processing space and for supporting the substrate; a nozzle for discharging a treatment solution onto the substrate when processing the substrate; and a liquid supply unit for supplying the nozzle with the treatment solution, in which the liquid supply unit includes: a liquid supply source for supplying the treatment solution; a supply line connected between the liquid supply source and the nozzle; a supply valve installed on the supply line and opening and closing a passage of the supply line; a first discharge line connected to the supply line, but connected downstream of the supply valve, and connected with a drain port for discharging the treatment solution, and connected downwardly from the supply line; a second discharge line connected to the drain port to be connected with the first discharge line, and discharging the treatment solution through the first discharge line, and connected downwardly from the first discharge line; a drain valve installed in the first discharge line, opening and closing a passage of the first discharge line, and disposed at a position lower than the supply valve; and an intermediate valve installed in the supply line, but installed downstream of the supply valve, and set to a closed state before the supply valve before the supply valve is set from an open state to a closed state, and disposed at a lower position than the supply valve, and the supply line includes: a first line in which the supply valve is installed; a second line extending from the first line and positioned lower than the first line, and connected with the first discharge line; and a third line extending upwardly from the second line and connected to the nozzle, and having a top end higher than a top end of the first line and a top end of the second line.

The present invention has the effect of preventing process failures caused by bubbles and particles because the bubbles generated by the intermediate valve when discharging the treatment solution through the nozzle are discharged through the first discharge line.

The effect of the present invention is not limited to the foregoing effects, and non-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a top plan view illustrating a substrate processing facility according to an exemplary embodiment of the present invention.

FIG. 2 is a cross-sectional view illustrating a substrate processing apparatus of FIG. 1.

FIG. 3 is a schematic cross-sectional view of a liquid supply unit illustrated in FIG. 2.

FIG. 4 is a systematic diagram of a modified example of the liquid supply unit illustrated in FIG. 3.

FIG. 5 is a systematic diagram of a modified example of the liquid supply unit illustrated in FIG. 4.

FIG. 6 is a flowchart of a substrate processing method according to an exemplary embodiment of the present invention.

FIGS. 7 to 11 are cross-sectional views illustrating open and closed states of the liquid supply unit for each of the operations illustrated in FIG. 6.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate processing, in addition to wafers.

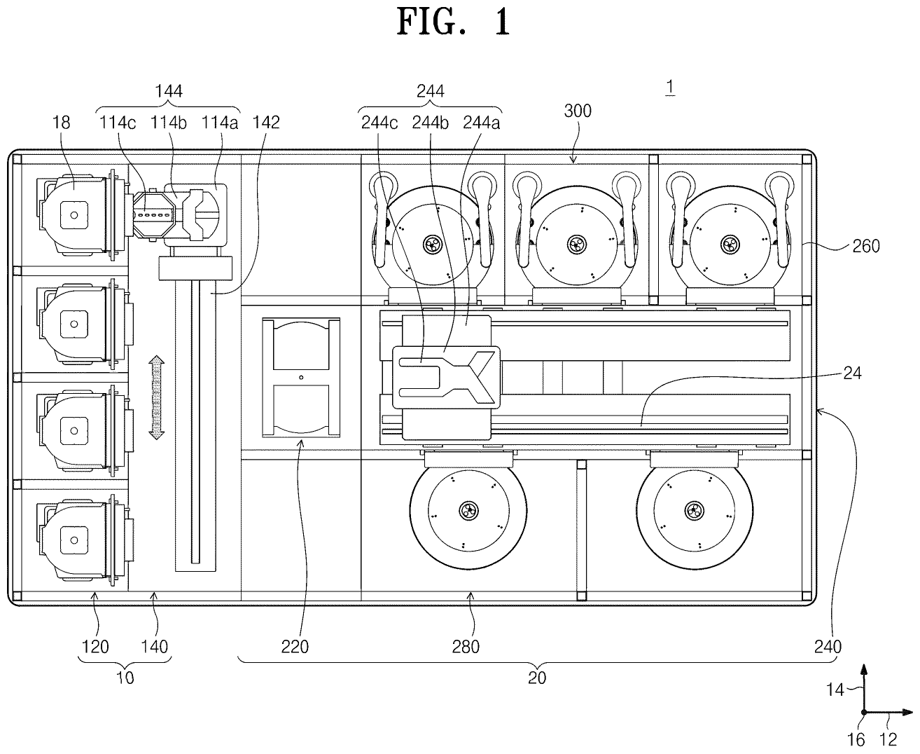

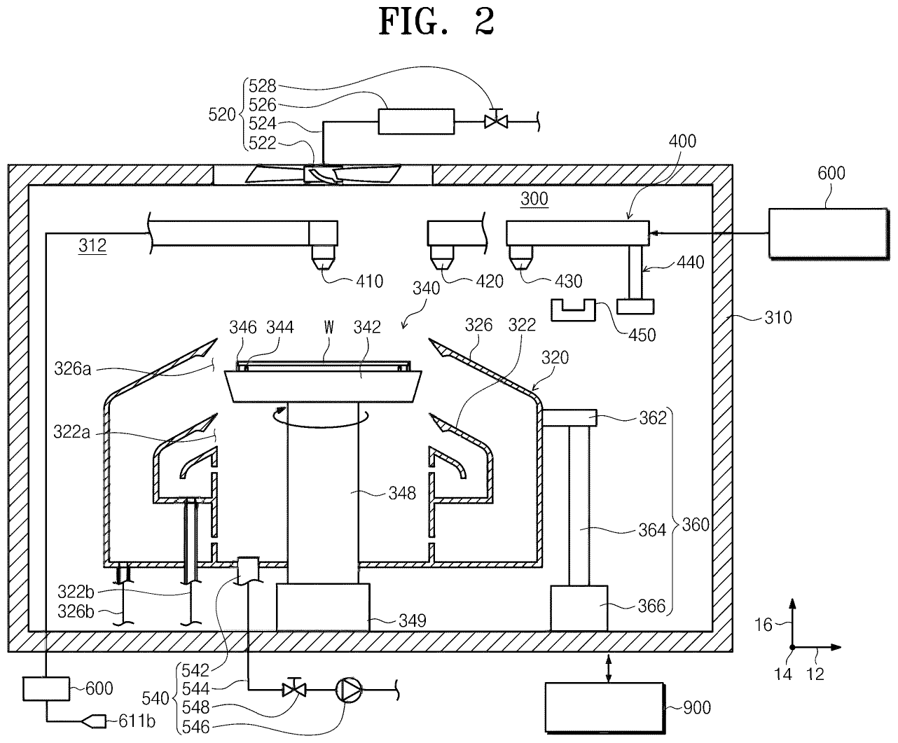

FIG. 1 is a top plan view illustrating a substrate processing facility according to an exemplary embodiment of the present invention. FIG. 2 is a cross-sectional view illustrating a substrate processing apparatus of FIG. 1.

Referring to FIGS. 1 and 2, a substrate processing facility 1 includes an index module 10 and a process processing module 20, and the index module 10 includes a load port 120 and a transfer frame 140. The load port 120, the transfer frame 140, and the process processing module 20 are arranged in sequential rows. Hereinafter, a direction in which the load port 120, the transfer frame 140, and the process processing module 20 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 18 in which a substrate W is accommodated is seated on the load port 120. A plurality of load ports 120 is provided, which are arranged in a row along the second direction 14.

In FIG. 1, it is illustrated that four load ports 120 are provided. However, the number of load ports 120 may be increased or decreased depending on conditions, such as process efficiency and footprint of the process processing module 20. Slots (not illustrated) provided to support an edge of the substrate are formed in the carrier 18. The slots are provided in a plurality in the third directions 16, and the substrates are located in a carrier to be stacked while being spaced apart from each other along the third directions 16. As the carrier 18, a Front Opening Unified Pod (FOUP) may be used.

The process processing module 20 may include a buffer unit 20, a transfer chamber 240, and process chambers 260 and 280. The transfer chamber 240 is disposed so that a longitudinal direction thereof is parallel to the first direction 12. The process chambers 260 and 280 are disposed on opposite sides of the transfer chamber 240 in the second direction 14. The process chambers 260 may be provided to be symmetrical to each other relative to the transfer chamber 240. Some of the process chambers 260 and 280 are disposed along the longitudinal direction of the transfer chamber 240. Additionally, some of the process chambers 260 and 280 are arranged to be stacked on top of each other. That is, the process chambers 260 and 280 may be disposed in an array of A×B (A and B are natural numbers equal to or greater than 1) on opposite sides of the transfer chamber 240. Here, A is the number of process chambers 260 and 280 provided in a line along the first direction 12, and B is the number of process chambers 260 and 280 provided in a line along the third direction 16. When four or six process chambers 260 and 280 are provided on each of the opposite sides of the transfer chamber 240, the process chambers 260 and 280 may be disposed in an array of 2×2 or 3×2. The number of process chambers 260 and 280 may be increased or decreased. Unlike the foregoing, the process chamber 260 may be provided only to one side of the transfer chamber 240. In addition, the process chambers 260 and 280 may be provided as a single layer on one side and the opposite sides of the transfer chamber 240. In addition, the process chambers 260 and 280 may be provided in various arrangements unlike the above.

The process chambers 260 and 280 of the present exemplary embodiment may be categorized as including a cleaning chamber and a drying chamber. In this case, the cleaning chamber may be a substrate processing facility for cleaning the substrate, which will be described below, and the drying chamber may be a substrate processing facility for drying the substrate.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. The buffer unit 220 is provided with slots (not illustrated) in which the substrate W is placed therein, and the slots (not illustrated) are provided in plural to be spaced apart from each other along the third direction 16. In the buffer unit 220, a side facing the transfer frame 140 and a side facing the transfer chamber 240 are each open.

The transfer frame 140 transfers the substrate W between the carrier 18 seated at the load port 120 and the buffer unit 220. The transfer frame 140 is provided with an index rail 142 and an index robot 144. The index rail 142 is provided so that a longitudinal direction thereof is parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 18, and another some of the plurality of index arms 144c may be used when the substrate W is transferred from the carrier 130 to the process processing module 20. This may prevent the particles generated from the substrate W before the process processing from being attached to the substrate W after the process processing in the process in which the index robot 144 loads and unloads the substrate W.

The transfer chamber 240 transfers the substrate W between the buffer unit 220 and the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b.

Hereinafter, a substrate processing apparatus 300 provided in the process chamber 260 will be described. In the present exemplary embodiment, the case where a substrate processing apparatus 300 performs a liquid treating process on the substrate will be described as an example. The liquid treating process further includes a process of cleaning a substrate.

FIG. 2 is a cross-sectional view illustrating a substrate processing apparatus of FIG. 1. Referring to FIG. 2, the substrate processing apparatus 300 further includes a chamber 310, a processing container 320, a support unit 340, a lifting unit 360, a liquid discharge unit 400, an airflow formation unit 500, a liquid supply unit 600, and a controller 900. The chamber 310 provides a processing space 312 in which a process for processing the substrate W is performed.

The processing container 320 is positioned in the processing space 312 and is provided in the shape of a cup with an open top. When viewed from above, the processing container 320 is positioned to overlap an exhaust pipe. The processing container 320 includes an internal recovery container 322 and an external recovery container 326. Each of the recovery containers 322 and 326 recovers a different treatment solution from the treatment solutions used in the process.

The internal recovery container 322 is provided in the shape of an annular ring surrounding the support unit 340, and the external recovery container 326 is provided in the shape of an annular ring surrounding the inner recovery container 322. An inner space 322a of the internal recovery container 322 and a space 326a between the external recovery container 326 and the internal recovery container 322 function as inlets for the treatment solution to flow into the internal recovery container 322 and the external recovery container 326, respectively. Recovery lines 322b and 326b are connected to the bottom surfaces of the recovery containers 322 and 326, respectively, to extend vertically in the down direction. Each of the recovery lines 322b and 326b functions as a discharge pipe to discharge the treatment solution that has been introduced through the respective recovery containers 322 and 326. The discharged treatment solution may be reused through an external treatment solution regeneration system (not illustrated).

The support unit 340 is provided as a substrate support unit 340 for supporting and rotating the substrate W. The support unit 340 is disposed within the processing container 320. The substrate support unit 340 supports the substrate W and rotates the substrate W during the process progress. The support unit 340 includes a spin chuck 342, a support pin 344, a chuck pin 346, and a rotation shaft 348. The spin chuck 342 has a top surface that is substantially circular when viewed from the top. The rotation shaft 348 that is rotatable by a driver is fixedly coupled to the bottom surface of the spin chuck 342. In one example, the driver may be formed of a motor 349. A plurality of support pins 344 is provided. The support pins 344 are spaced apart on the edge portion of a top surface of the spin chuck 342 and protrude upwardly from the spin chuck 342. The support pins 334 are arranged in combination with each other to have an overall annular ring shape. The support pin 344 supports an edge of the rear surface of the substrate W so that the substrate W is spaced apart from the top surface of the spin chuck 2631 at a predetermined distance. A plurality of chuck pins 346 is provided. The chuck pins 346 are disposed to be further away from a center of the spin chuck 342 than the support pins 344. The chuck pin 346 is provided to protrude upwardly from the spin chuck 342. The chuck pin 346 supports a lateral portion of the substrate W to prevent the substrate W from laterally deviating from its stationary position when the support unit 340 is rotated. The chuck pin 346 is provided to be linearly movable between a standby position and a support position along a radial direction of the spin chuck 342. The standby position is a position further away from the center of the spin chuck 342 relative to the support position. When the substrate W is loaded into or unloaded from the support unit 340, the chuck pin 346 is positioned in the standby position, and when a process is being performed on the substrate W, the chuck pin 346 is positioned in the support position. In the support position, the chuck pin 346 is in contact with the lateral portion of the substrate W.

The lifting unit 360 regulates the relative height between the processing container 320 and the support unit 340. The lifting unit 360 linearly moves the processing container 320 in the up and down direction. As the processing container 320 is moved up and down, the relative height of the processing container 320 with respect to the support unit 340 changes. The lifting unit 460 includes a bracket 360, a moving shaft 362, and a driver 364. The bracket 362 is fixedly installed on the outer wall of the processing container 320, and a moving shaft 364, which is moved in the vertical direction by a driver 366, is fixedly coupled to the bracket 364. When the substrate W is placed on the support unit 340 or lifted from the support unit 340, the processing container 320 is lowered so that the support unit 340 protrudes above the processing container 320. Furthermore, when the process is in progress, the height of the processing container 320 is regulated so that the treatment solution may flow into the preset recovery containers 322 and 326 according to the type of treatment solution that has been supplied to the substrate W.

Unlike the above description, the lifting unit 360 may move the support unit 340 in the upper and lower directions instead of the processing container 320.

The liquid discharge unit 400 supplies various types of liquids to the substrate W. The liquid discharge unit 400 further includes a plurality of nozzles 410 to 430. Each nozzle is moved to a process position and a standby position by a nozzle position driver 440. A process position is defined herein as a position where the nozzles 410 to 430 are capable of discharging liquid onto the substrate W positioned within the processing container 320, and a standby position is defined as a position where the nozzles 410 to 430 are waiting outside of the process position. According to an example, the process position may be a position at which the nozzles 410 to 430 may supply a liquid to the center of the substrate W. For example, when viewed from above, the nozzles 410 to 430 may be moved linearly or axially to be moved between the process position and the standby position. The treatment solution discharged from the liquid discharge unit 400 to the substrate W may be a treatment solution for processing the substrate W. Additionally, in the standby position, a recovery pipe 450 may be disposed below the third nozzle 430. The recovery pipe 450 recovers the treatment solution when the third nozzle 430 discharges the treatment solution for cleaning.

The plurality of nozzles 410 to 430 discharges different types of liquid. The treatment solution discharged from the nozzles 410 to 430 may include at least one of a chemical, a rinse solution, a cleaning solution, and a drying fluid. Referring to the exemplary embodiment of FIG. 2, a first nozzle 410 may be a nozzle for discharging chemicals. For example, the chemical may be a liquid capable of etching a film formed on the substrate W or removing particles remaining on the substrate W. The chemical may be a liquid having a property of strong acid or strong base. The chemical may include sulfuric acid, hydrofluoric acid, or ammonia. Further, the second nozzle 420 may be a nozzle for discharging a rinse solution. The rinse solution may be a solution capable of rinsing the chemicals remaining on the substrate W. For example, the rinse solution may be pure water. Further, the second nozzle 420 may be a nozzle that discharges a cleaning solution. The cleaning solution may be a solution that treats the support unit 340, the processing container 320, and the recovery pipe 450 after processing the substrate W. Further, the third nozzle 430 may be a nozzle for discharging a drying fluid. The drying fluid may be provided as a solution capable of substituting the residual rinse solution on the substrate W. The drying fluid may be a solution having lower surface tension than the rinse solution. The drying fluid may be an organic solvent. The drying fluid may be isopropyl alcohol (IPA). The third nozzle 430 may be connected to the liquid supply unit 600 to receive a supply of a drying fluid.

The airflow formation unit 500 forms a downward airflow in the processing space 312. The airflow formation unit 500 supplies airflow from a top portion of the chamber 310 and exhausts airflow from a lower portion of the chamber 310. The airflow formation unit 500 further includes an airflow supply unit 520 and an exhaust unit 540. The airflow supply unit 520 and the exhaust unit 540 are positioned facing each other in the vertical direction.

The airflow supply unit 520 supplies gas in the downward direction. The gas supplied from the airflow supply unit 520 may be air from which impurities are removed. The airflow supply unit 520 further includes a fan 522, an airflow supply line 524, a supply valve 528, and a filter 526. The fan 522 is installed on the ceiling surface of the chamber 310. When viewed from above, the fan 522 is positioned to face the processing container. The fan 522 may be positioned to provide air toward the substrate W positioned within the processing container. The airflow supply line 524 is connected to the fan 522 to supply air to the fan 522. A supply valve 528 is installed in the airflow supply line 524 to regulate the amount of airflow supplied. The filter 526 is installed in the airflow supply line 524 to filter the air. For example, the filter 526 may remove particles and moisture contained in the air.

The exhaust unit 540 exhausts the processing space 312. The exhaust unit 540 further includes an exhaust pipe 542, a pressure reducing member 546, and an exhaust valve 548. The exhaust pipe 542 is installed on the bottom surface of the chamber 310 and is provided as a pipe to exhaust the processing space 312. The exhaust pipe 542 is positioned such that an exhaust port faces upwardly. The exhaust pipe 542 is positioned such that the exhaust port is in communication with the interior of the processing container. That is, the top of the exhaust pipe 542 is located within the processing container. Accordingly, the downward airflow formed within the processing container is exhausted through the exhaust pipe 542.

The pressure reducing member 546 reduces pressure of the exhaust pipe 542. A negative pressure is formed in the exhaust pipe 542 by the pressure reducing member 546, which exhausts the processing container. The exhaust valve 548 is installed in the exhaust pipe 542 and opens and closes the exhaust port of the exhaust pipe 542. The exhaust valve 548 regulates the exhaust volume.

The liquid supply unit 600 may supply liquid to each of the plurality of nozzles 410 to 430.

The controller 900 controls the driving of the processing container 320, the support unit 340, the lifting unit 360, the liquid discharge unit 400, the airflow formation unit 500, and the liquid supply unit 600 with a preset process algorithm to process the substrate W.

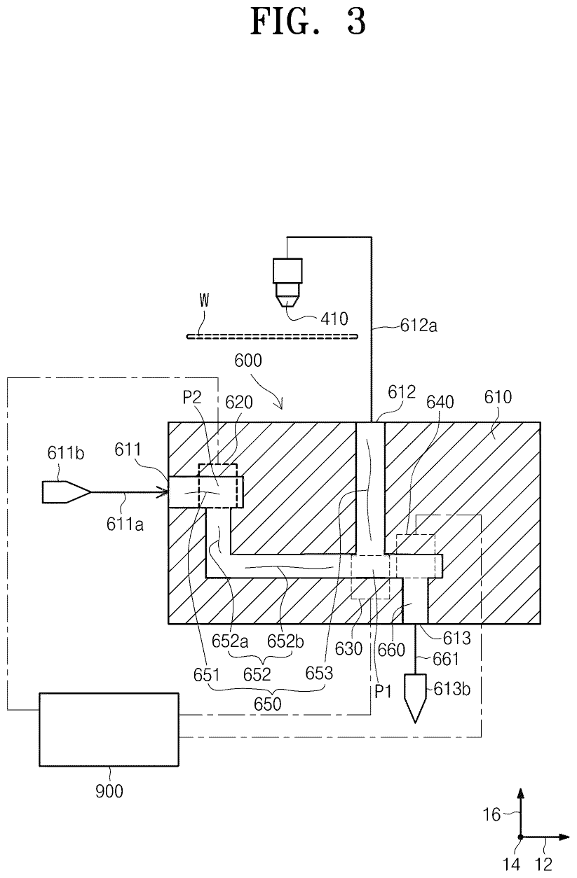

FIG. 3 is a schematic cross-sectional view of a liquid supply unit illustrated in FIG. 2.

As illustrated in FIG. 3, the liquid supply unit 600 may include a body 610, a supply valve 620, an intermediate valve 630, and a drain valve 640.

The body 610 forms a flow path through which the treatment solution flows. The body 610 is provided with an inlet port 611, an outlet port 612, and a drain port 613. The inlet port 611 is connected with an inlet line 611a that supplies the treatment solution to the flow path. The inlet line 611a receives a treatment fluid from a liquid supply source 611b. The outlet port 612 is connected to an outlet line 612a that receives the treatment fluid from the flow path. The outlet line 612a connects the outlet port 612 to the first nozzle 410. The drain port 613 is connected to a second discharge line 661 that receives the treatment fluid from the flow path. The second discharge line 661 may be connected to a treatment solution disposal source 613b, such as a drain tank to discharge the treatment solution, or may be connected to a recovery line (not illustrated) to be reused.

The body 610 may be provided with a supply line 650 and a first discharge line 660 of the discharge line. Each of the supply line 650 and the first discharge line 660 may be provided as a flow path through which the treatment solution flows on an interior side of the body 610, or may be provided as a separate line.

The supply line 650 includes a first line 651, a second line 652, and a third line 653.

The first line 651 is connected to the inlet port 611 and has a supply valve 620 installed.

The second line 652 extends downstream of the first line 651 and has the intermediate valve 630 installed. The second line 652 may include a second-1 line 652a extending downstream from the first line 651 and a second-2 line 652b extending laterally from the second-1 line 652a. The second line 652 may be positioned lower than the first line 651.

The third line 653 extends upwardly from downstream of the second line 652 and is connected with the outlet port 612. A top end of the third line 653 may be positioned higher than a top end of the second line 652. Further, the top end of the third line 653 may be positioned higher than a top end of the first line 651. Thus, the third line 653 may ensure that only the pressurized treatment solution is supplied to the first nozzle 410 side.

The first discharge line 660 extends downstream of the second line 652 and is connected to the drain port 613. The first discharge line 660 may be connected downwardly from the second line 652. Thus, the first discharge line 660 may have a lower end positioned lower than the second line 652 to discharge the treatment solution in a free fall. In another aspect, the discharge line may include the first discharge line 660, and a second discharge line 661 extending from the first discharge line 660. Here, the second discharge line 661 may be provided in a form that is connected externally to the body 610, when provided to the body 610.

The supply valve 620 opens and closes a passage in the flow path through which the treatment solution flows from the inlet port 611 to the outlet port 612. The supply valve 620 may be installed in the first line 651 of the flow path. The supply valve 620 is controlled to open and close from the controller 900. In one example, the supply valve 620 may be a diaphragm valve of which opening and closing of the disk is controlled by a solenoid.

The intermediate valve 630 opens and closes a passage through which the treatment fluid flows from the inlet port 611 to the outlet port 612 in the flow path. The intermediate valve 630 is installed in the second line 652. The intermediate valve 630 is installed downstream of the supply valve 620. In one example, the intermediate valve 630 may be a diaphragm valve of which opening and closing of the disk is controlled by a solenoid. The intermediate valve 630 is disposed at a lower position than the supply valve 620.

The drain valve 640 opens and closes a passage in the flow path through which treatment fluid flows from the inlet port 611 to the drain port 613. The drain valve 640 is installed in the first discharge line 660 of the flow path. The drain valve 640 is controlled to open and close from the controller 900. In one example, the drain valve 640 may be a diaphragm valve of which opening and closing of the disk is controlled by a solenoid. The drain valve 640 is disposed at a lower position than the supply valve 620.

In addition to the above forms, the liquid supply unit 600 may be modified into and implemented in various other forms, as described below.

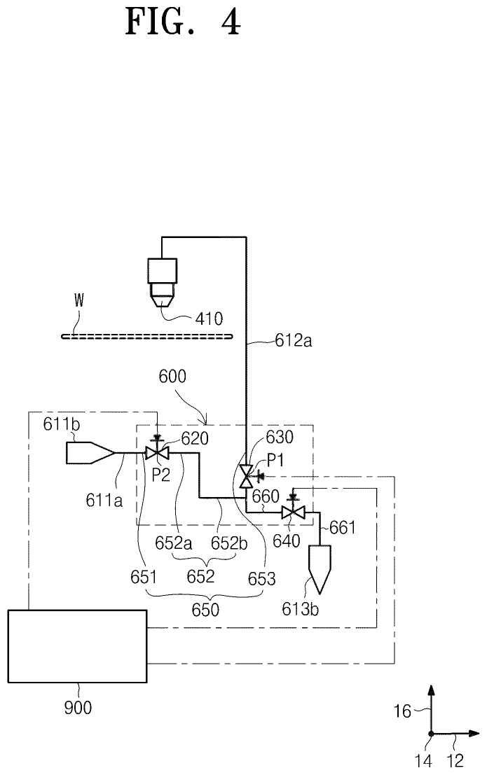

FIG. 4 is a systematic diagram of a modified example of the liquid supply unit illustrated in FIG. 3.

As illustrated in FIG. 4, the liquid supply unit 600 may also be modified to the form configuring lines by using a separate pipes, rather than including the first line 651, the second line 652, the third line 653, and the first discharge line 660 on the body 610.

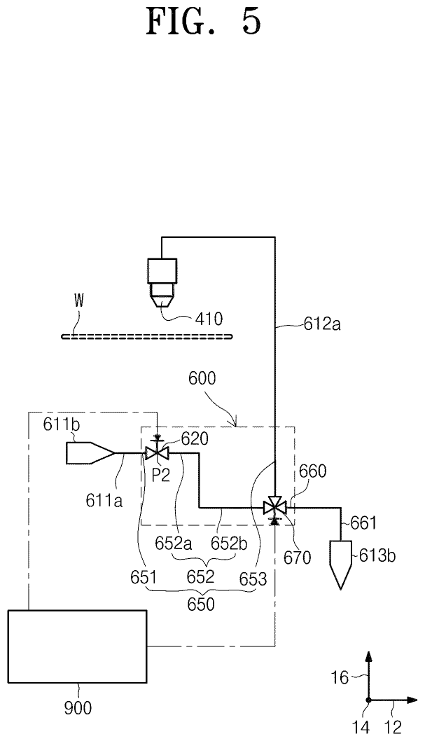

FIG. 5 is a systematic diagram of a modified example of the liquid supply unit illustrated in FIG. 4.

As illustrated in FIG. 5, the liquid supply unit 600 may further include a three-way valve 670. The three-way valve 670 may have three ports, and the open and closed states for each of the three ports may be individually controlled by the controller 900. As such, the three-way valve 670 implements the functions of the intermediate valve 630 and the drain valve 640 in the exemplary embodiment of FIG. 4 in a single valve. It should be appreciated, of course, that the intermediate valve 630 and drain valve 640 may be implemented not only as the three-way valve 670, but also as various other valves, such as a four-way valve (not illustrated) or a three-port four-position valve (not illustrated), as desired.

Hereinafter, a substrate processing method according to an exemplary embodiment of the present invention will be described.

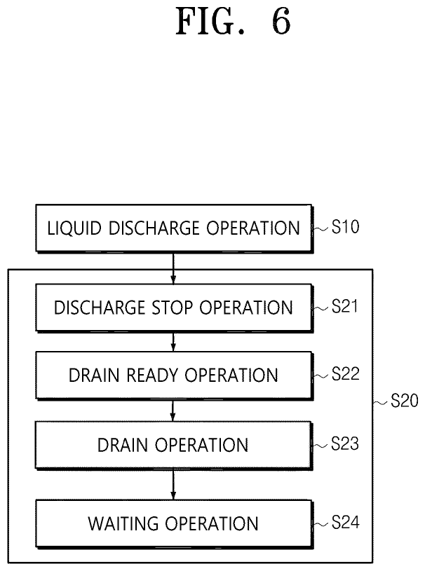

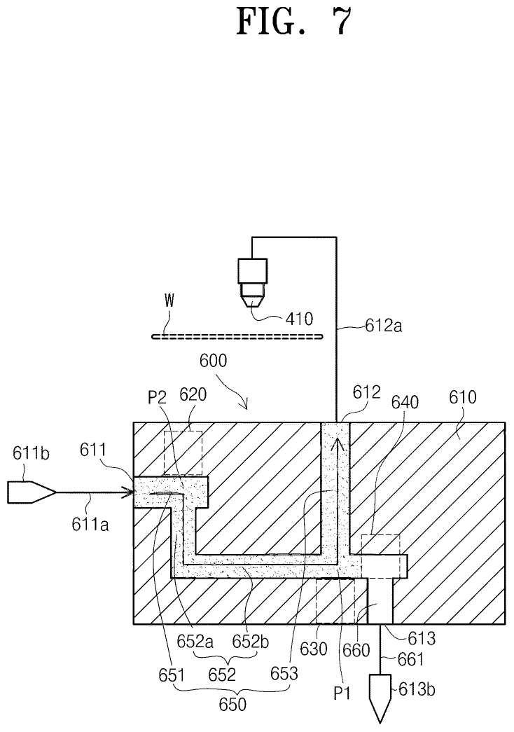

FIG. 6 is a flowchart of a substrate processing method according to an exemplary embodiment of the present invention. FIGS. 7 to 11 are cross-sectional views illustrating open and closed states of the liquid supply unit for each of the operations illustrated in FIG. 6.

As illustrated in FIG. 6, a substrate processing method according to an exemplary embodiment of the present invention includes a liquid discharge operation S10, and a treatment solution discharge operation S20.

The liquid discharge operation S10 is an operation of processing the substrate by setting the passage of the supply line 650 to an open state to supply the treatment solution to the first nozzle 410. In one example, in the liquid discharge operation S10, the supply valve 620 and the intermediate valve 630 are set to the open state by the controller 900, as illustrated in FIG. 7. The drain valve 640 may be set to a closed state. Thus, the treatment solution is discharged through the outlet port 612 by sequentially passing through the first line 651, the second line 652, and the third line 653 of the supply line 650, and the treatment solution discharged through the outlet port 612 is supplied to the first nozzle 410 side, and the treatment solution supplied to the first nozzle 410 side processes the substrate.

The treatment solution discharge operation S20 is an operation in which the bubble B1 and the treatment solution around the bubble B1 that occurs when switching the passage of the supply line 650 from the open state to the closed state are discharged through the first discharge line 660.

In one example, in the treatment solution discharge operation S20, when the first point P1 of the supply line 650 and the second point P2 located upstream of the first point P1 are set to an open state and the treatment solution is supplied to the first nozzle 410, the first point P1 is set to a closed state to allow the bubble B1 to be generated at the first point P1, and then the second point P2 is set to a closed state, and then the first point P1 and the first discharge line 660 are set to an open state to allow the bubble B1 and the treatment solution around the bubble B1 to be discharged through the first discharge line 660.

More specifically, the treatment solution discharge operation S20 may include a discharge stop operation S21, a drain ready operation S22, a drain operation S23, and a wait operation S24.

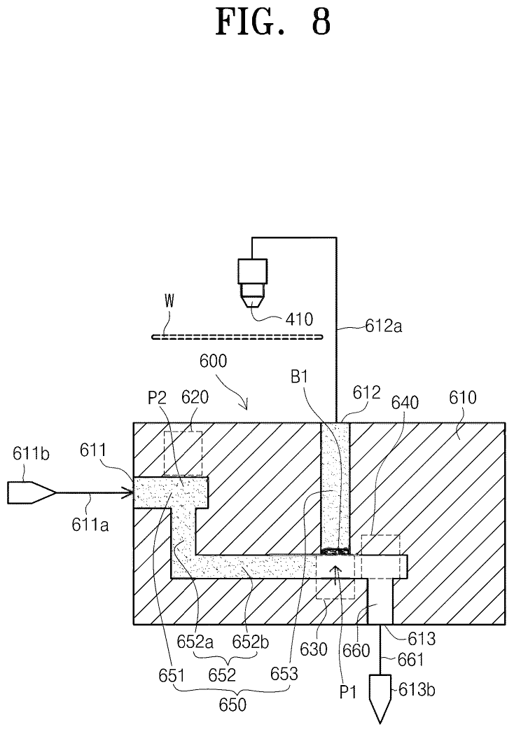

The discharge stop operation S21 is an operation to set the first point P1 of the supply line 650 from an open state to a closed state. In one example, in the discharge stop operation S21, by the controller 900, the supply valve 620 is set to remain open, the drain valve 640 is set to remain closed, and the intermediate valve 630 is set to a closed state, as illustrated in FIG. 8. In this case, the intermediate valve 630 is first set to the closed state before the supply valve 620 is set from the open state to the closed state. Accordingly, a sharp air pressure difference between the outlet port 612 and the inlet port 611 is created in the vicinity of the intermediate valve 630 by its rapidly closing driving.

This air pressure difference may form a bubble B1 around the vicinity of the intermediate valve 630. Here, the bubble B1 generated during the close driving of the intermediate valve 630 is formed on the side of the intermediate valve 630 rather than on the side of the supply valve 620. On the other hand, since the bubble B1 is generated by a sharp air pressure difference, it may generate a strong impact on the component around the bubble B1, which may wear the component around the bubble B1. As a result, particles may be generated around the bubble B1 due to the wear. For example, the area around the disk of the intermediate valve 630 may be subject to particles of the disk worn along with the bubble B1. When the bubble B1 and the particles are generated as described above, the bubble B1 and the particles are discharged through the first nozzle 410 onto the substrate and cause process failures, so that the bubble B1 and the particles need to be removed.

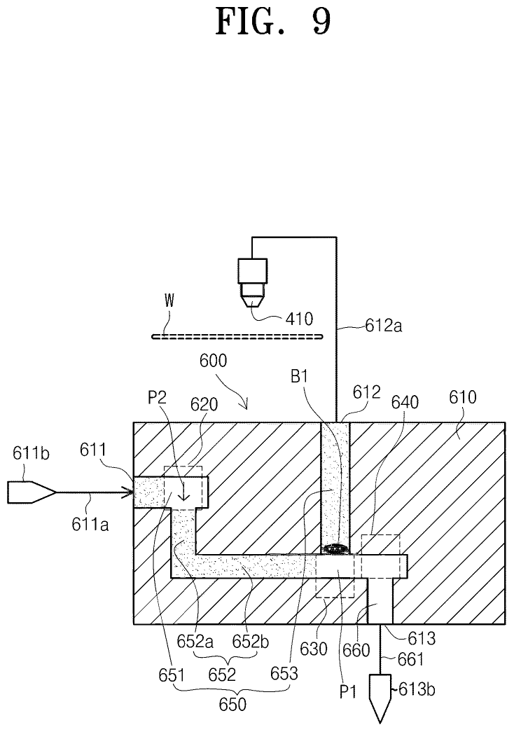

The drain ready operation S22 is an operation of setting the second point P2, which is located upstream of the first point P1 in the supply line 650, to a closed state. In one example, the drain ready operation S22 may including setting the supply valve 620 to a closed state in a state where the intermediate valve 630 and the drain valve 640 remain closed by the controller 900, as illustrated in FIG. 9.

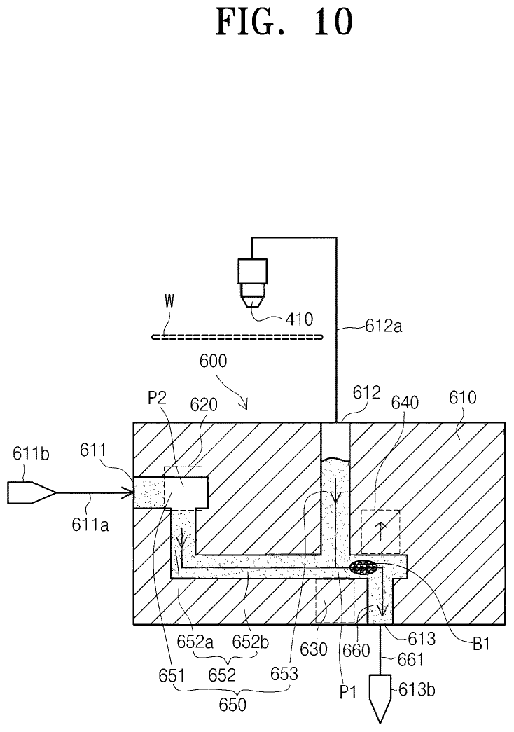

The drain operation S23 is an operation of setting the first point P1 of the supply line 650 to an open state, and setting the passage of the first discharge line 660 to an open state to drain the bubble B1 and the treatment solution around the bubble B1 through the first discharge line 660. In one example, in the drain operation S23, by the controller 900, the supply valve 620 is set to the closed state and the intermediate valve 630 and the drain valve 640 are set to the open state, as illustrated in FIG. 10. The supply line 650 is in a state where, with respect to the second point P2, the upstream side is sealed and pressurized, and the downstream side is exposed to atmospheric pressure. Thus, the bubble B1 is discharged along the first discharge line 660 of the flow path to the drain port 613.

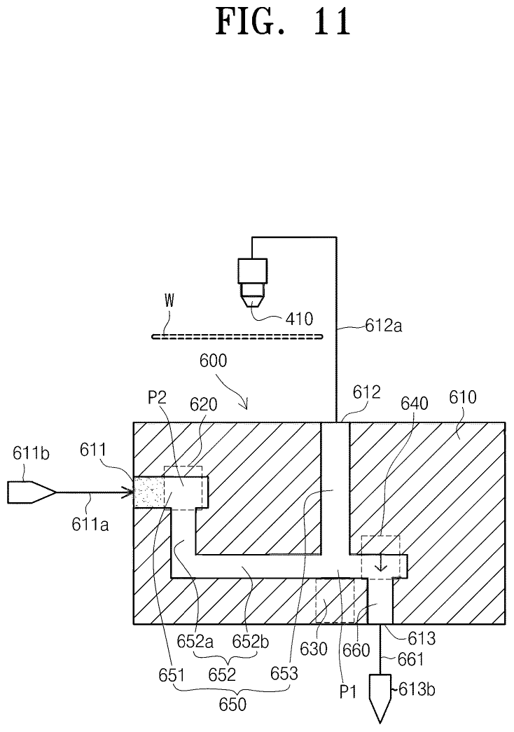

The waiting operation S24 is an operation in which the bubble B1 of the supply line 650 and the treatment solution around the bubble B1 are discharged through the first discharge line 660, and then the passage of the first discharge line 660 is set to a closed state. In one example, in the waiting operation S24, the supply valve 620 is set to the closed state, the intermediate valve 630 is set to the open state, and the drain valve 640 is set to the closed state by the controller 900, as illustrated in FIG. 11. The waiting operation S24 proceeds in the state where the treatment solution has been completely discharged through the drain port 613 the drain operation S23. After the waiting operation S24, the liquid discharge operation S10 and subsequent operations described above may be performed again in sequence to process treat the substrate with the treatment solution.

As described above, the substrate processing apparatus and the substrate processing method according to the exemplary embodiments of the present invention may prevent process failure caused by the bubble B1 because the bubble B1 generated at the intermediate valve 630 when discharging the treatment solution through the first nozzle 410 are discharged through the first discharge line 660.

As described above, the present invention has been described with reference to the specific matters, such as a specific component, limited exemplary embodiments, and drawings, but these are provided only for helping general understanding of the present invention, and the present invention is not limited to the aforementioned exemplary embodiments, and those skilled in the art will appreciate that various changes and modifications are possible from the description.

Therefore, the spirit of the present invention should not be limited to the described exemplary embodiments, and it will be the that not only the claims to be described later, but also all modifications equivalent to the claims belong to the scope of the present invention.

1. An apparatus for processing a substrate, the apparatus comprising:
a chamber having a processing space for processing a substrate;
a support unit disposed in the processing space and for supporting the substrate;
a nozzle for discharging a treatment solution onto the substrate when processing the substrate; and
a liquid supply unit for supplying the nozzle with the treatment solution,
wherein the liquid supply unit includes:
a liquid supply source for supplying the treatment solution;
a supply line connected between the liquid supply source and the nozzle;
a supply valve installed on the supply line and opening and closing a passage of the supply line;
a discharge line connected to the supply line downstream of the supply valve and discharging the treatment solution from the supply line; and
a drain valve installed on the discharge line and opening and closing a passage of the discharge line.

2. The apparatus of claim 1, wherein the discharge line is connected to the supply line so as to extend downwardly from the supply line.

3. The apparatus of claim 1, wherein the drain valve is disposed at a lower position than the supply valve.

4. The apparatus of claim 1, wherein the liquid supply unit further includes an intermediate valve that is installed in the supply line, but is installed downstream of the supply valve.

5. The apparatus of claim 4, further comprising:
a controller for controlling the supply valve, the drain valve, and the intermediate valve,
wherein the controller controls the intermediate valve and the supply valve such that the intermediate valve is set to a closed state before the supply valve before the supply valve is set from an open state to a closed state.

6. The apparatus of claim 5, wherein the intermediate valve is disposed at a lower position than the supply valve.

7. The apparatus of claim 4, wherein the intermediate valve is a diaphragm valve of which opening and closing of a disk is controlled by a solenoid.

8. The apparatus of claim 1, wherein the supply line includes:
a first line in which the supply valve is installed; and
a second line extending from the first line and positioned lower than the first line, and
the discharge line is connected to the second line.

9. The apparatus of claim 8, wherein the supply line further includes a third line connected upwardly from the second line and connected with the nozzle, and
a top end of the third line is higher than a top end of the first line and a top end of the second line.

10. The apparatus of claim 1, further comprising:
a controller for controlling the supply valve and the drain valve,
wherein when, in the supply line, the supply line is in a closed state and the drain valve is in an open state by the controller, an upstream side of the supply valve is sealed and a downstream side of the supply valve is exposed to atmospheric pressure to cause the treatment solution to be drained by free fall.

11. The apparatus of claim 1, wherein the supply valve and the drain valve are diaphragm valves of which opening and closing of a disk is controlled by a solenoid.

12. (canceled)

13. (canceled)

14. (canceled)

15. (canceled)

16. (canceled)

17. (canceled)

18. (canceled)

19. (canceled)

20. An apparatus for processing a substrate, the apparatus comprising:
a chamber having a processing space for processing a substrate;
a support unit disposed in the processing space and for supporting the substrate;
a nozzle for discharging a treatment solution onto the substrate when processing the substrate; and
a liquid supply unit for supplying the nozzle with the treatment solution,
wherein the liquid supply unit includes:
a liquid supply source for supplying the treatment solution;
a supply line connected between the liquid supply source and the nozzle;
a supply valve installed on the supply line and opening and closing a passage of the supply line;
a first discharge line connected to the supply line, but connected downstream of the supply valve, and connected with a drain port for discharging the treatment solution, and connected downwardly from the supply line;
a second discharge line connected to the drain port to be connected with the first discharge line, and discharging the treatment solution through the first discharge line, and connected downwardly from the first discharge line;
a drain valve installed in the first discharge line, opening and closing a passage of the first discharge line, and disposed at a position lower than the supply valve; and
an intermediate valve installed in the supply line, but installed downstream of the supply valve, and set to a closed state before the supply valve before the supply valve is set from an open state to a closed state, and disposed at a lower position than the supply valve, and
the supply line includes:
a first line in which the supply valve is installed;
a second line extending from the first line and positioned lower than the first line, and connected with the first discharge line; and
a third line extending upwardly from the second line and connected to the nozzle, and having a top end higher than a top end of the first line and a top end of the second line.
